(19) United States
(12) Patent Application Publication
(10) Pub. No.: US 2017/0148942 A1
(43) Pub. Date: May 25, 2017

(54) SOLAR PANEL AND METHOD OF MANUFACTURING SUCH A SOLAR PANEL

(71) Applicant: STICHTING ENERGIEONDERZOEK CENTRUM NEDERLAND, Petten (NL)

(72) Inventors: Johannes Adrianus Maria VAN ROOSMALEN, Petten (NL); Ian John BENNETT, Petten (NL); Evert Eugène BENDE, Petten (NL)

(21) Appl. No.: 15/325,567

(22) PCT Filed: Jul. 13, 2015
(86) PCT No.: PCT/EP2015/065991

§ 371 Date: Jan. 11, 2017

(30) Foreign Application Priority Data
Jul. 11, 2014 (NL) 2013168

(51) Int. Cl. H01L 31/054; H01L 31/0236; H01L 31/05; H02S 30/10; H01L 31/18; H01L 31/02; H01L 31/048; H01L 31/068

(52) U.S. Cl. CPC H01L 31/0547; H01L 31/048; H01L 31/02366; H01L 31/0684; H02S 30/10; H01L 31/18; H01L 31/0201; H01L 31/0508

(57) ABSTRACT

A solar panel (1) includes: a plurality of semiconductor substrate based solar cells (2), a transparent front side plate (4), and a rear side plate (6). The transparent front side plate (4) is stacked on top of the rear side plate (6) and the plurality of solar cells (2) are arranged in an array in between the rear side (6) plate and the front side plate (4). Each solar cell (2) has a light receiving surface facing (8) towards the front side plate (4); the solar cells (2) being embedded in an encapsulant layer (10) between the front side plate (4) and the rear side plate (6), wherein the solar panel includes an internal light redirection unit (12; 20) for guiding light received on the solar panel (1) but not captured by the solar cells (2), towards the solar cells (2).

### FIELD OF THE INVENTION

The present invention relates to a solar panel for receiving light from a radiation source, in particular to a solar panel with an improved efficiency. In a further aspect the present invention relates to a method for manufacturing a solar panel.

### PRIOR ART

In standard crystalline silicon based solar panels, a part of the solar panel surface area is taken up by solar cells and a part is not. Those parts that are not taken up by solar cells are gaps represented by the areas in between the solar cells, typically 1 to 3 mm wide, and the area around an array of solar cells up to the frame or edges of the solar panel.

The effective area of a solar panel to capture radiation energy is smaller than the size of the solar panel.

In standard solar panels from the prior art the area between the solar cells is not completely lost for power generation. A part of incident light in these areas is reflected from a white reflective back sheet via the front glass panel to the solar cells. The additional power from these areas can be in the order of 1-2%.

Additionally, now that solar panels are applied increasingly on/in buildings and other infrastructure related applications, such as sound barriers, it is observed that the appearance of solar panels often has an aesthetical mismatch with the appearance of the building.

It is an object of the present invention to overcome or mitigate the drawbacks of the prior art.

### SUMMARY OF THE INVENTION

The present invention seeks to provide an improved solar panel for receiving light from a radiation source, wherein the solar panel exhibits an improved efficiency in converting light to usable electrical power.

According to the present invention, a solar panel for receiving light from a radiation source of the type defined in the preamble is provided, in which the solar panel comprises:

comprising a plurality of semiconductor substrate based solar cells, a transparent front side plate, and a rear side plate; the transparent front side plate being stacked on top of the rear side plate; the plurality of solar cells being arranged in an array in between the rear side plate and the front side plate, each solar cell having a light receiving surface facing towards the front side plate; the solar cells being embedded in an encapsulant layer between the front side plate and the rear side plate, wherein the solar panel comprises between the front side plate and the rear side plate internal light redirection means for guiding light received on the solar panel but not captured by the solar cells, towards the solar cells, wherein the solar panel further comprises a frame or an edge and the solar cells are placed at predetermined positions relative to each other with a first intermediate area between each two adjacent solar cells and a second intermediate area between the frame or edge and each solar cell adjacent to the frame or edge; wherein the solar panel comprises a light scattering area for scattering light towards the solar cells; the light scattering area corresponding substantially with a location of either the first intermediate area, the second intermediate area, or a combination thereof and optionally with a third intermediate area defined by an intermediate cross section area of adjacent rows and adjacent columns of solar cells in the array arrangement, wherein the solar panel further comprises a light scattering area for scattering light towards the solar cells; the light scattering area corresponding substantially with a location of either the first intermediate area, the second intermediate area, the third intermediate area, or a combination thereof, and wherein the light scattering area is a coloured layer arranged for scattering at least a portion of light originating from the radiation source, the portion of light being in the (near) infrared range of the spectrum.

The solar panel of the present invention offers improved efficiency through the internal redirection layer which is configured for guiding incident light in the (near) infrared on the solar panel between solar cells, towards the solar cells. As such, a portion of incident light on the solar panel that would normally not be absorbed, is further utilised for conversion efficiency and power output purposes.

According to an aspect, the present invention relates to a solar cell as described above, wherein the light scattering area is arranged for scattering at least a portion of light originating from the radiation source.

According to an aspect, the present invention relates to a solar cell as described above, wherein the light scattering area is a coloured layer arranged for absorbing visible light portion from the radiation source and for scattering at least a portion of light originating from the radiation source, the portion of light being in the (near) infrared range of the spectrum.

According to an aspect, the present invention relates to a solar cell as described above, wherein the light scattering area is a light scattering layer arranged at a same level substantially perpendicular from the front side plate as a level of the solar cells between the front side plate and the rear side plate, the light scattering area being embedded between an upper and lower encapsulant layer.

According to an aspect, the present invention relates to a solar cell as described above, wherein the light scattering area is arranged at a level between the front side plate and a level of the solar cells in the solar panel.

According to an aspect, the present invention relates to a solar cell as described above, wherein the light scattering area is arranged at a level from the front side plate between the level of the solar cells and the rear side plate in the solar panel.

According to an aspect, the present invention relates to a solar cell as described above, wherein the light scattering area is a light scattering layer comprising a substance having light scattering particles therein.

According to an aspect, the present invention relates to a solar cell as described above, wherein the light scattering layer is embodied by a patterned foil with openings, each with a size corresponding with the size of a solar cell and the pattern of openings corresponding with the positions of the solar cells in the array.

According to an aspect, the present invention relates to a solar cell as described above, wherein the patterned foil comprises a polymer with a melting point higher than a lamination temperature during manufacturing of the solar panel.

According to an aspect, the present invention relates to a solar cell as described above, wherein the substance is a paint or an ink.

According to an aspect, the present invention relates to a solar cell as described above, wherein the rear side plate is transparent to light.

According to an aspect, the present invention relates to a solar cell as described above, wherein the solar cells are bifacial solar cells.

According to an aspect, the present invention relates to a solar cell as described above, wherein the solar cells are interconnected in the array by tab connections or bussings.

According to an aspect, the present invention relates to a solar cell as described above, wherein the tab connections and/or bussings are covered by the light scattering area in a direction towards at least one of the front side plate and the rear side plate.

According to an aspect, the present invention relates to a method for manufacturing a solar panel comprising: providing a transparent front side plate and a rear side plate; providing a plurality of solar cells, each being based on a semiconductor substrate and capable of generating photoelectricity from captured radiation energy;

arranging the solar cells in between the transparent front side plate and rear side plate, the solar cells being arranged in an array in between the rear side plate and the front side plate, each solar cell having a light receiving surface facing towards the front side plate, and the solar cells being embedded in an encapsulant layer between the front side plate and the rear side plate; and arranging in the solar panel between the front side plate and the rear side plate internal light redirection means for guiding light received on the solar panel but not captured by the solar cells, towards the solar cells.

Other advantageous embodiments are defined by the accompanying claims.

### SHORT DESCRIPTION OF DRAWINGS

The present invention will be discussed in further detail hereinafter based on a number of exemplary embodiments with reference to the drawings, wherein:

FIG. 1A and 1B each show an embodiment of a solar panel according to the present invention;

FIG. 2 shows a cross sectional view of a solar panel according to the present invention;

FIGS. 3 to 5 each show embodiments of a light scattering area of a solar panel according to the present invention;

FIG. 6 shows a top view of an embodiment of a light scattering layer having a patterned foil according to the present invention;

FIGS. 7 and 8 each show an embodiment of a reflecting area underneath a solar cell according to the present invention;

FIG. 9 shows an embodiment of a reflecting layer having a varying refractive index according to the present invention;

FIG. 10 shows an embodiment of a tab connection provided with a light redirection means according to the present invention, and

FIGS. 11A, 11B show a plane view of tab connections between a pair of solar cells in a solar panel according to an embodiment of the present invention.

### DETAILED DESCRIPTION OF EXEMPLARY EMBODIMENTS

For aesthetical purposes it may be desirable to have “black” solar panels, i.e. having black (or in general coloured) areas that are not taken up by solar cells. According to an embodiment of the invention, this is done by using a black back sheet or a black encapsulant layer, which can be formed either by pigment or ink added to an encapsulant polymer or by a sandwich construction of a coloured sheet with the encapsulant layer. However, the invention recognizes that the black material usually absorbs all light and does not contribute to the conversion efficiency and power output of the solar panel.

In standard modules such as p-type mc-Si H-pattern modules, the rear of the solar cells (the non-light receiving surface) is not transparent to light and solutions that make use of a uniform approach for the entire rear side can be applied. However, new technologies are under development that have different designs, such as Metal Wrap Through (MWT) solar panels, wherein a copper back sheet is used which metal parts may disturb the optical appearance and performance of the solar panel and n-type monocrystalline silicon solar cells where the rear side of the solar cell is for a large part transparent to light, similar to the front side of the solar cell. Their use in modules may benefit from a non-uniform approach as well as the use of bifacial solar cells in bifacial modules.

In bifacial solar panels a transparent back side is applied, such as a transparent back sheet or glass, to allow that the solar cells can received light at their front and rear sides. In standard bifacial modules a transparent front side plate and a transparent rear side plate are used as well as a transparent encapsulant. This may not be optimal with respect to performance and appearance.

According to the invention, there is thus a need for an aesthetic solar panel design with improved conversion efficiency. The solar panel of the present invention fulfils this need.

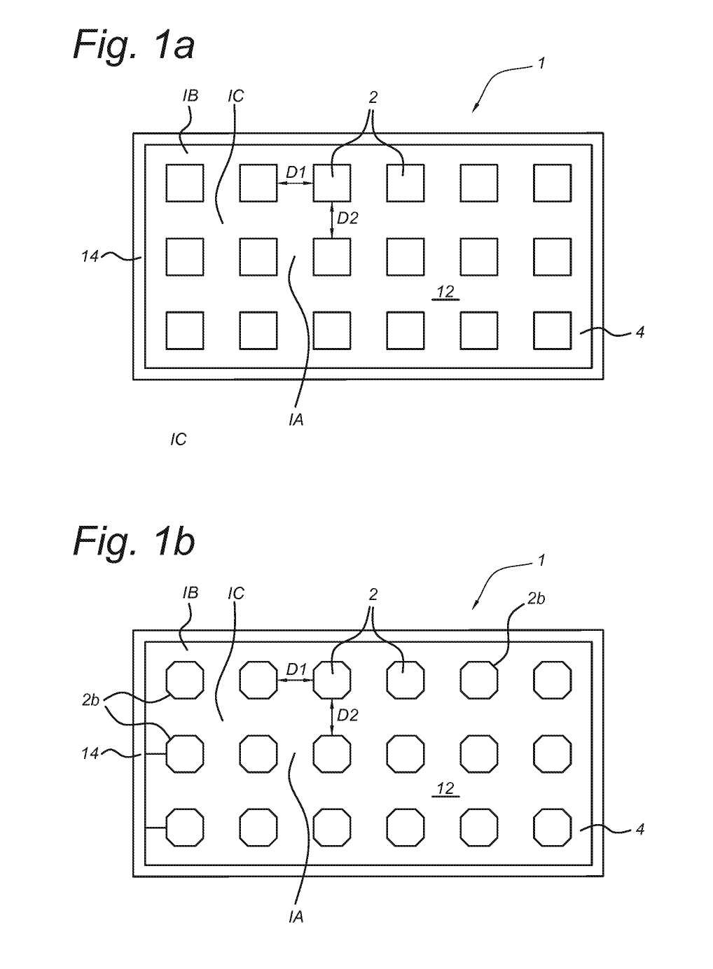

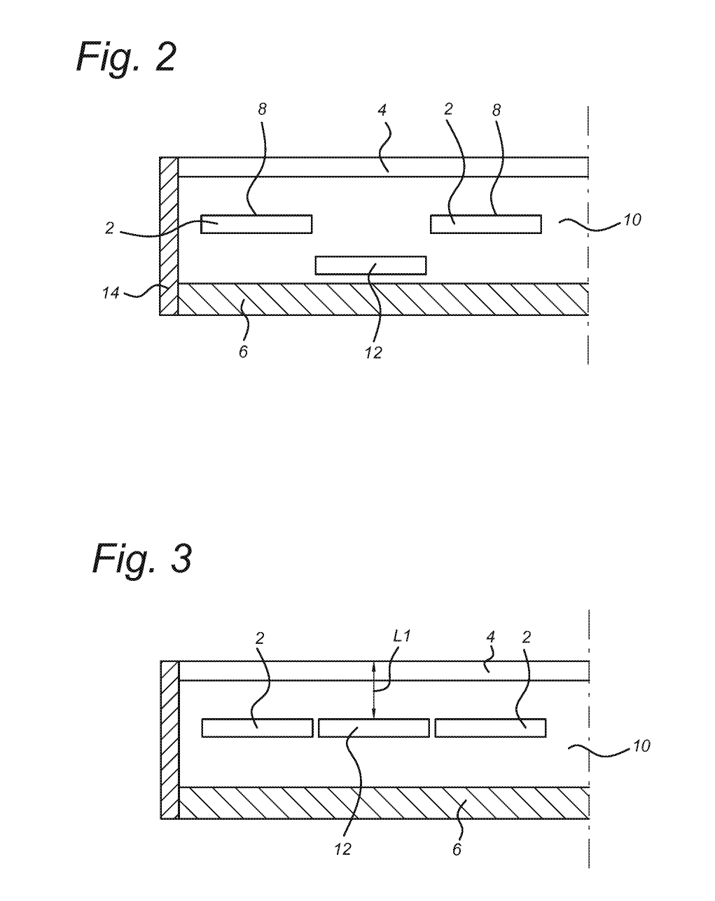

FIGS. 1A, 1B and 2 respectively show a top view and cross sectional view of an embodiment of a solar panel according to the present invention.

In the embodiments shown, the solar panel 1 comprises a plurality of semiconductor substrate based solar cells 2 disposed between a transparent front side plate 4 and a rear side plate 6. As depicted, the transparent front side plate 4 is stacked on top of the rear side plate 6, wherein the plurality of solar cells 2 are regularly arranged in an array therebetween.

Each solar cell 2 is provided with a light receiving surface 8 facing towards the front side plate 4, wherein for strengthening and other purposes the plurality of solar cells 2 are embedded in an encapsulant layer 10 between the front side plate 4 and the rear side plate 6.

According to the invention, the solar panel 1 further comprises an internal light redirection layer for guiding light that is received on the solar panel 1 but not captured by the solar cells 2, towards the solar cells 2. That is, incident light on the solar panel 1 but not incident on, or not absorbed by, the solar cells 2 is redirected by the internal light redirection layer towards the solar cells 2. As a result, incident light that would normally not be captured by the plurality of solar cells 2 may at least in part be redirected by the internal redirection layer and converted by the solar cells 2 into usable electrical power, thereby increasing conversion efficiency of the solar panel 1.

In an embodiment, the solar panel 1 further comprises a frame 14, wherein the solar cells 2 are placed at predetermined positions d1, d2 relative to each other. The frame 14 may be circumferentially disposed around the solar panel 1 for e.g. structural stiffness. Further, a first intermediate area IA between each two adjacent solar cells 2 may be provided as well as a second intermediate area IB between the frame 14 and each solar cell 2 adjacent to said frame 14. In this embodiment the first and second intermediate areas IA, IB can be envisaged as padding around each solar cell 2. A third intermediate area IC may also be provided at an intermediate cross section area of adjacent rows and adjacent columns of solar cells 2 in the array arrangement. For example, in the embodiments shown in FIG. 1A and 1B, the third intermediate area IC corresponds to an area between four corners of neighbouring solar cells 2.

This embodiment further comprises a light scattering area 12 for scattering light towards the solar cells 2, wherein the light scattering area 12 corresponds substantially with a location of either the first intermediate area IA, the second intermediate area IB, the third intermediate area IC, or any combination thereof.

Without any limitation of the scope of the invention, in some situations, the predetermined positions d1, d2 or widths of the first intermediate areas IA are 1 to 4 mm.

For aesthetical purposes these areas can be enlarged beyond 4 mm, however reducing the overall cost effectiveness of electricity production by the solar panel. Intermediate areas 1B are typically in the range of 9 to 40 mm, complying at least to the minimum distance required for isolation of the internal electrical circuitry of the module to the outside world. Modules without frame (frameless modules) are also known, however, still a minimum distance between the cells and the edge of the module is required.

According to the invention, it will be appreciated that the solar cells 2 may in fact have various shapes and may be arranged and distributed within the solar panel 1 in various ways. For example, FIG. 1A depicts an embodiment wherein the solar cells 2 have a substantially rectangular or square shape and are regularly arranged. FIG. 1B on the other hand depicts an embodiment having a regular arrangement of solar cells 2 with a polygon shape such as an octagon, e.g. a square having cut off corners 2b.

So in view of the invention, the light scattering area 12 may be embodied by a general area between solar cells 2, regardless of the actual shape and arrangement of the solar cells 2 with respect to each other.

It will be appreciated that the figures do not necessarily depict the correct scale and, as such, are drawn for illustrative purposes. Advantageously, the light scattering area 12 may be arranged for scattering at least a portion of light originating from the radiation source, thereby utilizing incident light on the solar panel 1 between the solar cells 12 for improving conversion efficiency.

In light of the present invention and ease of reference, the term “scattering” may be interpreted as diffuse reflection but also as specular reflection (i.e. mirror-like reflection).

For aesthetical reasons, the first, second, and third intermediate areas IA, IB, IC may have e.g. a black colour. However, as black generally absorbs large portions of light, the first, second and third intermediate areas IA, IB, IC may provide a sub-optimal improvement of the efficiency of the solar cell 2.

According to an embodiment of the present invention, to improve the efficiency of the solar cell 2 even in case the first, second and third intermediate areas IA, IB, IC absorb large portions of light, it is provided that the light scattering area 12 is arranged for scattering at least a portion of light originating from the radiation source, wherein the portion of light is in the infrared (IR) range of the spectrum. Hence, in this embodiment the light scattering area 12 is configured for scattering incident infrared radiation towards the solar cells 2, thereby improving power output of the solar cells 2 without sacrificing aesthetical requirements of the solar panel 1, i.e. having a substantially black colour. Of course, any colour may be used for the solar panel provided the light scattering area 12 is configured for scattering light from the infrared (IR) range of the spectrum.

Thus according to an embodiment, the light scattering area is a light scattering layer that is capable of absorbing light in the visible part of the spectrum and reflecting or transmitting light in the infrared part of the spectrum.

In case the light scattering layer can transmit infrared light, reflection of such radiation can be obtained by means of a IR reflecting interface in or IR reflecting surface of the solar panel.

In an embodiment, the light scattering layer comprises at least one pigment that is capable of scattering infrared radiation. The pigment may have a specific colour in the visible range of the spectrum.

FIGS. 3 to 5 each show embodiments of a light scattering area 12 of a solar panel 1 according to the present invention. In the embodiments shown the light scattering area 12 is disposed at various levels or depths within the solar panel 1.

In the embodiment shown in FIG. 3, the light scattering area 12 is arranged at a same level L1 from the front side plate 4 as a level of the solar cells 2 between the front side plate 4 and the rear side plate 6, wherein the light scattering area 12 may be disposed in the encapsulant layer 10. This embodiment is advantageous for enhancing the performance of the solar panel 1, wherein IR reflection/scattering may also further contribute to the performance of the solar panel 1. Further, bifacial solar panels 1 may benefit from this particular embodiment as bifacial solar panels absorb light from both sides.

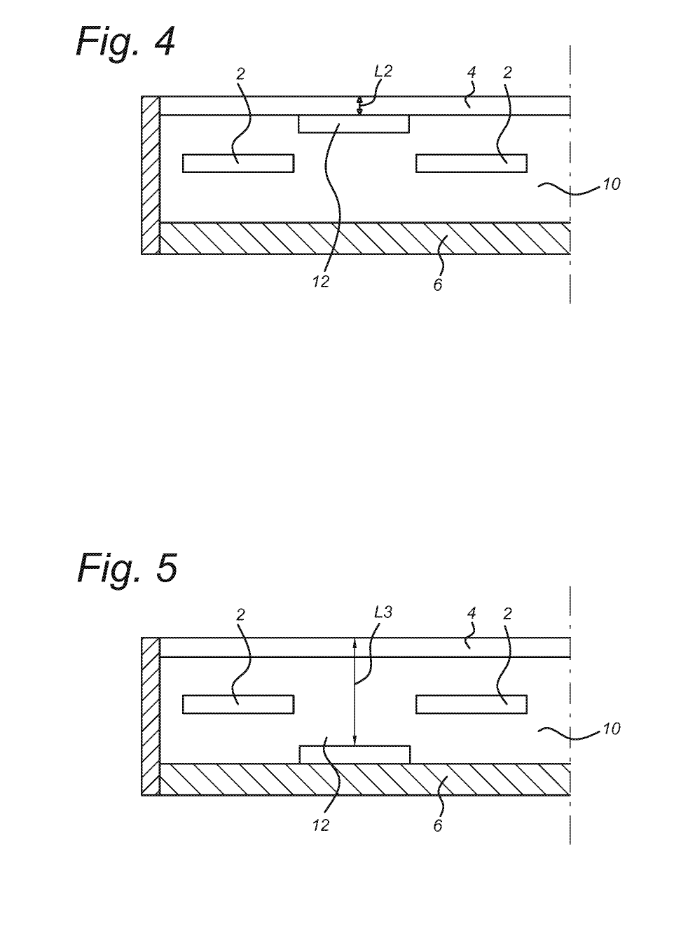

In the embodiment shown in FIG. 4, the light scattering area 12 is arranged at a level L2 between the front side plate 4 and a level of the solar cells 2 in the solar panel 1. In this embodiment, the light scattering area 12 increases the amount of incident light on the solar cells 2 from a front plate 4 direction and scatters incident light virtually immediately once the incident light traverses the front side plate 4 or via reflection via the front glass panel to the solar cells.

In the embodiment of FIG. 5, the light scattering area 12 is arranged at a level L3 from the front side plate 4 between a level of the solar cells 2 and the rear side plate 6 in the solar panel 1. It should be noted that in this embodiment the light scattering area 12 may extend beyond the first or second intermediate area IA, IB and may partially extend underneath the solar cells 2. As such, poorly absorbed IR light by the solar cells 2 may be scattered or reflected back towards the solar cells 2 for improved efficiency and power output of the solar panel 1. Further, note that the light scattering area 12 in the embodiment of FIG. 4 and FIG. 5 may or may not be located in the encapsulant layer 10.

An important aspect of the present invention is that in the embodiments of FIGS. 3, 4 and 5 the improved conversion efficiency of the solar panel 1 may be attributed to both forward scattering as well as backward scattering by the light scattering area 12. In particular, forward scattered light passing through the light scattering area 12 may be either transmitted directly or reflected via the back side plate 6 toward the solar cells 2, whereas backward scattered light by the light scattering area 12 may be reflected via the front side plate 4 toward the solar cells 2. This forward and backward scattering mechanism associated with the light scattering area 12 may exist independent of the depth level L1, L2, L3 at which the light scattered area 12 is located. In advantageous embodiments, the back side plate 6 may be a glass plate for optimizing reflection of forward scattered light by the light scattering area 12 toward the solar cells 2.

In an embodiment, the light scattering area 12 may be envisaged as a light scattering layer. Such a light scattering layer may either be part of or be sandwiched (e.g., laminated or co-extruded) with the encapsulant layer. In particular, the light scattering area 12 may be a light scattering layer comprising a substance having light scattering particles. Such light scattering particles may be easily dispersed in the first, second and third intermediate areas IA, IB, IC providing the desired scattering of incident visible light and IR light thereon. In an advantageous embodiment, the substance comprises a paint layer, which may have light scattering particles. The paint layer is readily applied to e.g. the rear side plate 6 in the first, second and/or third intermediate areas IA, IB, IC, thereby improving the efficiency and power output of the solar panel 1 by scattering/reflecting incident light on the paint layer towards the solar cells 2. Alternatively the paint layer can be replaced with or in addition be provided with any other layer consisting of or comprising light scattering material, e.g. mixtures of pigments with binders and/or adhesives, encapsulant material etc., applied by any means, e.g. painting, spraying, powder coating, printing, jetting, casting, dispensing etc.

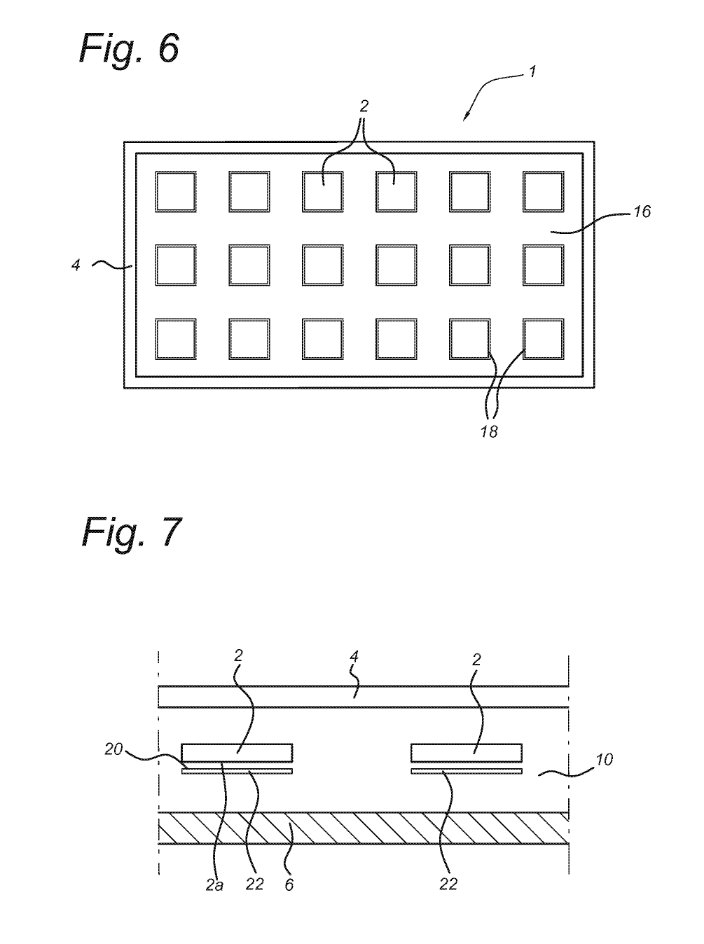

In another embodiment, as depicted in FIG. 6, the light scattering layer 12 may also be a patterned foil 16 with openings or apertures 18, each with a substantially same size as a solar cell 2, wherein the pattern of openings 18 corresponds with the positions of the solar cells 2 in the array. Put differently, the opening or apertures 18 of the patterned foil 16 enclose the solar cells 1 in a snug fashion. In a typical embodiment, the patterned foil 16 may be disposed in the encapsulate layer 10, wherein the solar cells 2 extend through the openings 18 in a snug fit therewith. As such, the patterned foil 16 may also provide further structural stiffness to the solar panel 1 and the relative positions of the solar cells 2, thereby not only improving the conversion efficiency and power output of the solar panel 1, but also extending the usable life time and durability of the solar panel 1.

The patterned foil may either consist of a sheet material or may be constructed from individual parts, e.g. foil or tape formed to the desired dimensions of areas IA and IB.

As shown in FIG. 3, the patterned foil may be arranged at a same level L1 substantially perpendicular from the front side plate 4 as a level of the solar cells 2 between the front side plate 4 and the rear side plate 6. The patterned foil is embedded between the upper and lower encapsulant layers.

In an embodiment, the patterned foil 16 may also be disposed or arranged at a level L2 between the front side plate 4 and a level of the solar cells 2 in the solar panel 1. Alternatively, the patterned foil 16 may also be disposed or arranged at a level L3 between the rear side plate 6 and a level of the solar cells 2 in the solar panel 1.

In an embodiment, the patterned foil comprises a polymer material that has a melting temperature higher than the temperature required for lamination during manufacturing of the solar panel.

In a further embodiment, the polymer material of the patterned foil comprises a PET (Polyethylene terephthalate) polymer. Typically, the melting temperature of PET is higher than a melting or flow temperature of an encapsulant such as Ethylene-vinyl acetate (EVA).

According to the invention, the material of the light scattering area is arranged with the property that near infrared (NIR) radiation sources, and optionally infrared (IR) sources, or even visible light sources, are scattered and may be captured by the solar cells 2 through the light scattering area 12 disposed in the first, second and/or third intermediate areas IA, IB, IC. To that end, the solar cells 2 may be placed at predetermined positions d1, d2 relative to each other with the first intermediate area IA interposed between each two adjacent solar cells 2 and the second intermediate area IB interposed between the frame 14 (or peripheral edge) of the solar panel and each solar cell 2 adjacent to the frame 14. In order to increase the conversion efficiency and power output of the solar panel 1 even further, the solar panel 1 may further comprise at the rear side between at least one solar cell 2 and the rear side plate 2 a reflecting area 20, whereby a non-absorbed portion of visible light, near infrared light (NIR), or infrared light (IR) still passing through the at least one solar cells 2 may be captured by scattering or reflection thereof towards the at least one solar cell 2. So in this particular embodiment non-absorbed radiation (e.g. visible, NIR, IR) passing through the solar cells 2 may still contribute to the conversion efficiency and power output of the solar panel 1.

Note that the term “visible light” may be construed as having a wavelength between e.g. 400 nm and 700 nm. The term “near infrared” (NIR) may be construed as having a wavelength between e.g. 700 nm and 1100 nm, and the term “infrared” (IR) or “infrared range” may be construed as having a wavelength between e.g. 700 nm and 50 μm.

For the purpose of photovoltaic conversion by the solar cell, the effective range for infrared radiation will be between about 700 nm and about 1100 nm for silicon based solar cells.

So in view of the invention the solar cells 2 may not only absorb visible light for conversion purposes and electrical power output, but also near infrared (NIR) or even infrared (IR) radiation may conceivably be absorbed by the solar cells 2 by direct absorption thereof and/or via the forward or backward scattering mechanism disclosed earlier. As such the solar panel 1 of the present invention exhibits a considerably higher conversion efficiency and electrical power output whilst providing an aesthetically appealing panel surface.

Moreover, for at least a portion of the radiation, the light scattering area 12 also provides scattering of radiation directed out of the solar panel, effectively contributing to relatively cooler operation of the solar panel. If this radiation would not be reflected, but absorbed, e.g. for a black solar panel, this would contribute to heating of the solar panel's components, reducing the overall power production of the solar panel and shortening components lifetime.

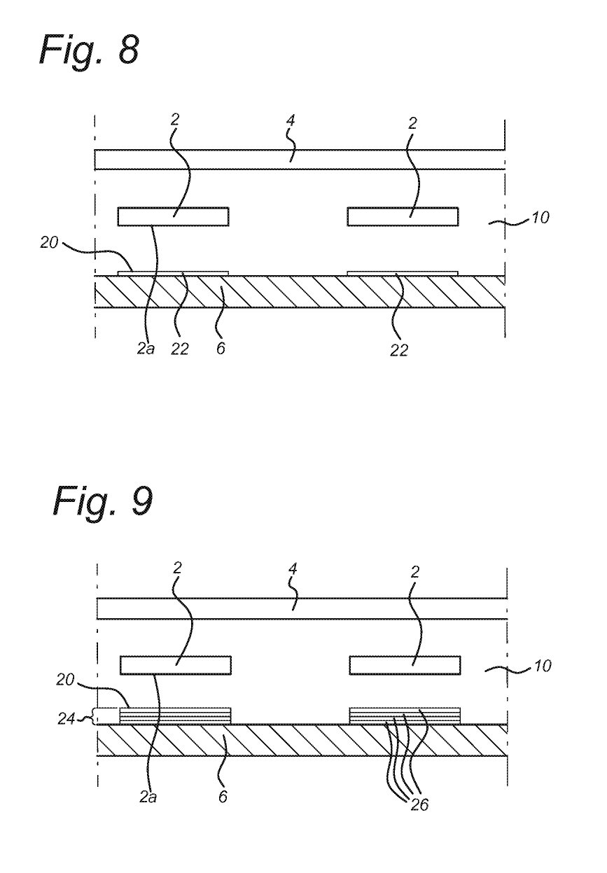

FIGS. 7 and 8 each show an embodiment of a reflecting area 20 underneath a solar cell 2 according to the present invention. In the embodiment shown, the reflecting area 20 may be embodied as an air gap 22 or as a refractive material 22 having a refractive index similar to that of an air gap, wherein a change of refractive index by the air gap or refractive material 22 causes non-absorbed light (e.g. visible, NIR, IR) to be reflected back in the solar cells 2. The air gap or refractive material 22 may be arranged between either a rear surface 2a of the at least one solar cell 2 and the encapsulant layer 10 or the encapsulant layer 10 and the rear side plate 6. In both of these depicted embodiments the refractive index may be optimized for reflecting back non-absorbed light radiation (e.g. visible, NIR, IR) passing though the solar cells 2. In a specific embodiment the air gap or refractive material 22 may have a thickness of about 50-about 1000 μm for optimal reflection.

In modules, air gaps may be undesirable to prevent the accumulation (condensation) of moisture or unpractical to realize because of mechanical integrity. Therefore the air gap can be realized by applying a layer of material that has air enclosures, effectively lowering the refractive index of the material to below that of the encapsulant material, e.g. between 1.2 and 1.5. The air enclosures remain during processing i.e. are not filled by the encapsulant material upon processing/lamination.

Alternatively the air gap can be realized by applying a material (e.g. polymer) that has a low refractive index (between 1.3 and 1.5 or lower than that of the encapsulant) by itself.

In typical embodiments, the reflection area 20 such as the air gap or a layer of refractive material 22 may be disposed underneath the solar cells 2, e.g. underneath the rear surface 2a, wherein the reflection area 20 has a width smaller than or equal to a width of the solar cell 2 as depicted in FIGS. 7 and 8. However, in some embodiments the reflection area 20 may have a larger width than the solar cell 2, thereby extending into the first and/or second intermediate areas IA, IB. These embodiments also increase the conversion and power output of the solar panel 1.

According to the invention, conversion efficiency and power output of the solar panel 1 can be improved by reflecting or scattering non-absorbed light passing through the solar cell 2 by means of the air gap or the layer of refractive material 22, which causes a change in the refractive index so that the non-absorbed light is redirected to the solar cell 2.

FIG. 9 depicts an embodiment wherein the light reflecting area 20 comprises a reflecting layer 24 with a low refractive index that is lower than each of a refractive index of the front side plate 4, a refractive index of the rear side plate 6 and a refractive index of the encapsulant layer 10. These variations of the respective refractive indices create a reflecting area that allows non-absorbed light to be redirected to the solar cell 2.

In an advantageous embodiment, the reflecting layer 24 comprises a gradient material with an effective refractive index varying from a relatively high refractive index at location closer to the solar cell 2 to a relatively lower refractive index at location closer to the rear side plate 6. This gradient material optimizes reflection properties of the reflecting area 20 or reflecting layer 24 for reflecting non-absorbed (IR) light to the solar cell 2, thus contributing to an improved conversion efficiency and power output of the solar panel 1. As depicted in FIG. 9, the reflecting layer 24 may comprise stacked sub-layers 26 of different materials. This stacked arrangement of sub-layers 26 may be adapted to attain required reflection properties for further conversion and power output improvements of the solar panel 1.

According to the invention, the above described embodiments may be applied to standard H-pattern and Metal Wrap-Through (MWT) solar panels 1, which typically comprise an opaque side, such as an opaque rear side panel 6. However, the present invention is not limited to one-side light receiving solar panels 1 having an opaque back sheet, rear side panel 6 and the like.

Indeed, according to the invention the rear side plate 6 may be transparent to light, i.e. the solar panel is bifacial.

In some embodiments the solar cells 2 may be bifacial solar cells 2, which are configured for absorbing incident light radiation from both sides of the solar panel 1 by the internal redirection means, such as the light scattering area 12, reflecting area 20 or reflecting layer 24, as described in the above embodiments.

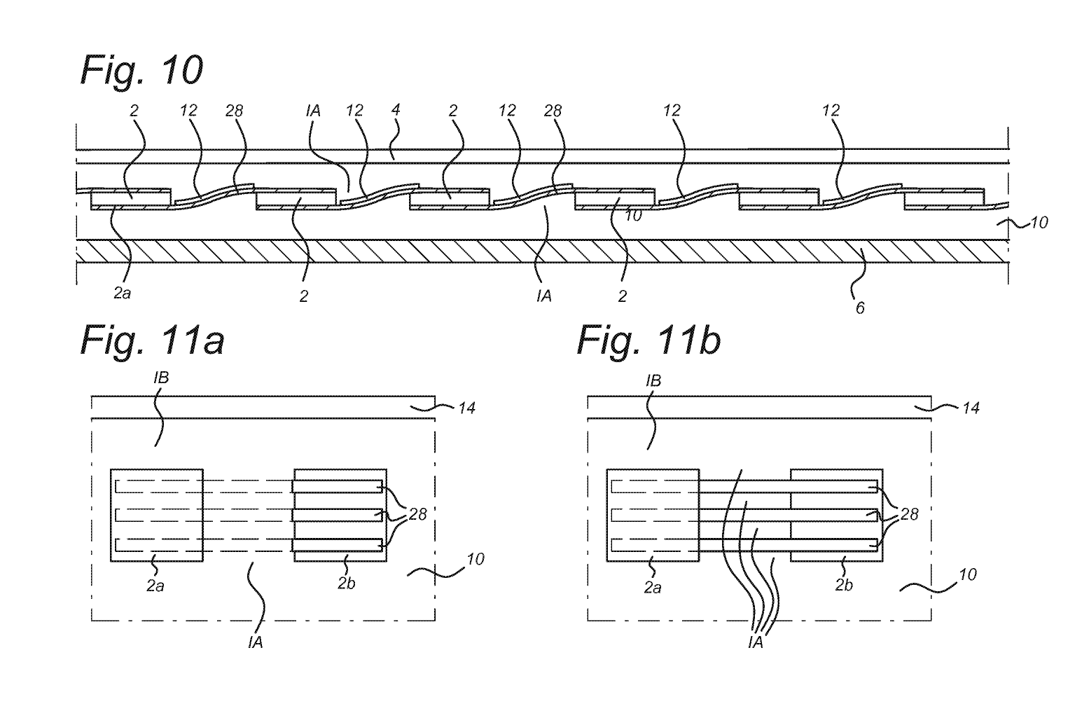

FIG. 10 shows a cross-section view of an embodiment of a solar panel 1 according to the present invention. In this embodiment, the solar cells 2 are interconnected in the array by tab connections 28. The tab connections 28, such as metallic tab connections 28, electrically connect side surfaces of two solar cells 2 in an alternating fashion as depicted, such as interconnecting a light receiving surface 8 of a first solar cell 2 and a rear surface 2a of an adjacent second solar cell 2. Note that the tab connections 28 may also connect all solar cells 2 in a row in alternating fashion.

In many embodiments, the tab connections 28 extend through the first intermediate area IA. However, since metallic tab connections 28 generally have strong light reflective properties, the first intermediate area IA may exhibit suboptimal scattering properties for improving conversion efficiency and power output of the solar panel 1.

According to the present invention, however, the solar panel 1 having a plurality of tab connections 28 interconnecting a plurality of solar cells 2 may still exhibit improved efficiency. To that end, in an embodiment the tab connections 28 may be covered by the light scattering area 12 in a direction towards at least one of the front side plate 4 and the rear side plate 6. This embodiment ensures light (e.g. visible, NIR, IR) scattering towards the front side plate 4 or the rear side plate 6, whereby scattered light can be reflected back towards the solar cells 2 for improved efficiency and power output.

In further embodiments, rows and/or columns of solar cells 2 as depicted in FIG. 1A, 1B and FIG. 6 are interconnected through specialised tab connections also known as metallic (cross) bussings. In such embodiment these bussings may also be covered by the light scattering area 12 in a direction towards at least one of the front side plate 4 and the rear side plate 6. That is, in an embodiment a light scattering area 12 is disposed above and/or below the (cross) bussings for scattering incident light thereon towards the solar cells 2.

It should be noted that the light scattering area 12 need not be in contact with the bussings and/or the tabs, so that a part of the encapsulant layer 10 may be interposed between the light scattering area 12 and the (cross) bussings and/or tabs.

FIG. 11A, 11B, show a plane view of tab connections between a pair of solar cells in a solar panel according to an embodiment of the present invention.

In FIG. 11A, a pair of solar cells 2a, 2b adjacent to each other is shown. Between a rear side of one 2a of the solar cells and a front side of the other 2b of the solar cells a set of three parallel tab connections 28 is shown. The part of the tab connections below the one solar cell 2a, is shown in dashed lines. The part of the tab connections above the other solar cell 2b is shown in solid lines. For reason of clarity, overlapping tab connections of other solar cells in the same row are not shown.

According to the embodiment shown in FIG. 11A, the light scattering area 12 is present in the first intermediate area IA between the solar cells 2a, 2b and overlaps the tab connections 28 in the first intermediate area IA as is indicated by the dashed lines. Optionally, in this embodiment, a second light scattering area may be located below the tab connection in the first intermediate area IA.

In FIG. 11B, the situation is shown where the tab connections in the first intermediate area are above the light scattering area 12. Alternatively, in an embodiment, the first intermediate area IA is arranged with the light scattering area 12, but the light scattering area 12 is interrupted at the locations of the tab connections 28 in the first intermediate area IA.

In the embodiments of FIG. 11A, 11B, the second intermediate area IB between solar cells and the edge 14 of the solar panel may or may not be provided with a light scattering area 12.

With reference to the above description, it is noted that the light scattering area can alternatively be embodied by an application of an ink comprising light scattering particles as described in more detail above on a layer component of the solar panel: a back sheet, a back encapsulant, a rear glass a front glass, and/or a front encapsulant. Also, the ink can comprise (granulated) encapsulant particles or an encapsulant precursor to obtain a better adhesion of the ink on the layer component of the solar panel.

The ink can be applied in various manners such as printing, spraying, dispensing, inkjet, or powder coating. Also application by means of a ‘sticker’, foil, gasket, tape, that comprises the ink with light scattering particles therein is conceivable.

Additionally, the light scattering area can be created by application of such a light scattering area in a laminated sheet, as a separate layer with light scattering properties as described in more detail above, e.g. gasket or tape, or diamond ‘stickers’ (e.g. square or circle or any suitable shape). The separate layer can comprise an adhesive component (e.g. encapsulant material) on one or both sides or not. In the latter case, it should adhere well to the encapsulant that is used in the module.

Also the light scattering area can be applied on a back-sheet by co-extrusion of a layer with light scattering properties and the layer of the back-sheet.

The present invention embodiments have been described above with reference to a number of exemplary embodiments as shown in and described with reference to the drawings. Modifications and alternative implementations of some parts or elements are possible, and are included in the scope of protection as defined in the appended claims.

The invention may be further defined by some embodiments that are described by the following clauses or aspects:

Clause 1. Solar panel 1 for receiving light from a radiation source comprising a plurality of semiconductor substrate based solar cells 2, a transparent front side plate 4, and a rear side plate 6; the transparent front side plate 4 being stacked on top of the rear side plate 6; the plurality of solar cells 2 being arranged in an array in between the rear side 6 plate and the front side plate 4, each solar cell 2 having a light receiving surface facing 8 towards the front side plate 4; the solar cells 2 being embedded in an encapsulant layer 10 between the front side plate 4 and the rear side plate 6, wherein the solar panel comprises between the front side plate and the rear side plate internal light redirection means 12; 20 for guiding light received on the solar panel 1 but not captured by the solar cells 2, towards the solar cells 2.

Clause 2. The solar panel according to clause 1, wherein the solar panel further comprises a frame 14 or an edge, wherein the solar cells 2 are placed at predetermined positions d1, d2 relative to each other with a first intermediate area IA between each two adjacent solar cells 2 and a second intermediate area IB between the frame 14 or edge and each solar cell 2 adjacent to the frame 14 or edge; wherein the solar panel 1 comprises a light scattering area 12 for scattering light towards the solar cells 2; the light scattering area 12 corresponding substantially with a location of either the first intermediate area IA, the second intermediate area IB, or a combination thereof.

Clause 3. The solar panel according to clause 2, wherein the solar cells 2 are placed at predetermined positions d1, d2 relative to each other with a third intermediate area IC defined by an intermediate cross section area of adjacent rows and adjacent columns of solar cells 2 in the array arrangement, wherein the solar panel 1 further comprises a light scattering area 12 for scattering light towards the solar cells 2; the light scattering area 12 corresponding substantially with a location of either the first intermediate area IA, the second intermediate area IB, the third intermediate area IC, or a combination thereof.

Clause 4. The solar panel according to any one of the preceding clauses 2-3, wherein the light scattering area 12 is a light scattering layer arranged at a same level L1 substantially perpendicular from the front side plate 4 as a level of the solar cells 2 between the front side plate 4 and the rear side plate 6, the light scattering area being embedded between an upper and lower encapsulant layer.

Clause 5. The solar panel according to clause 1, wherein the solar cells 2 are placed at predetermined positions d1, d2 relative to each other with a first intermediate area IA between each two adjacent solar cells 2 and a second intermediate area IB between the frame 14 and each solar cell 2 adjacent to the frame 14, wherein the solar panel 1 comprises at the rear side between at least one solar cell 2 and the rear side plate 2 a reflecting area 20.

Clause 6. The solar panel according to clause 5, wherein the reflecting area 20 is embodied as an air gap 22 or as a layer of a refractive material 22 having air enclosures that effectively lower a refractive index of the reflecting area below that of the encapsulant material .

Clause 7. The solar panel according to clause 6, wherein the air gap or the layer of refractive material 22 is arranged between either the rear surface 2a of the at least one solar cell 2 and the encapsulant layer 10, or the encapsulant layer 10 and the rear side plate 6.

Clause 8. The solar panel according to clause 6 or 7, wherein the air gap or the layer of refractive material 22 has a thickness of about 50-about 1000 μm.

Clause 9. The solar panel according to clause 5, wherein the light reflecting area 20 comprises a reflecting layer 24 with low refractive index that is lower than each of a refractive index of the front side plate 4, a refractive index of the rear side plate 6 and a refractive index of the encapsulant layer 10.

Clause 10. The solar panel according to clause 9, wherein the reflecting layer 24 comprises a gradient material with an effective refractive index varying over the thickness of said layer 24 from a relatively high refractive index at a location closer to the solar cell 2 to a relatively lower refractive index at a location closer to the rear side plate 6.

Clause 11. The solar panel according to clause 9 or clause 10, wherein the reflecting layer 24 comprises a stack of sub layers 26 of different materials.

Clause 12. Solar panel 1 for receiving light from a radiation source comprising a plurality of semiconductor substrate based solar cells 2, a transparent front side plate 4, and a rear side plate 6; the transparent front side plate 4 being stacked on top of the rear side plate 6; the plurality of solar cells 2 being arranged in an array in between the rear side 6 plate and the front side plate 4, each solar cell 2 having a light receiving surface facing 8 towards the front side plate 4; the solar cells 2 being embedded in an encapsulant layer 10 between the front side plate 4 and the rear side plate 6, wherein the solar panel comprises between the front side plate and the rear side plate internal light redirection means 12; 20 for guiding light received on the solar panel 1 but not captured by the solar cells 2, towards the solar cells 2, wherein the solar panel further comprises a frame 14 or an edge and the solar cells 2 are placed at predetermined positions d1, d2 relative to each other with a first intermediate area IA between each two adjacent solar cells 2 and a second intermediate area IB between the frame 14 or edge and each solar cell 2 adjacent to the frame 14 or edge; wherein the solar panel 1 comprises a light scattering area 12 for scattering light towards the solar cells 2; the light scattering area 12 corresponding substantially with a location of either the first intermediate area IA, the second intermediate area IB, or a combination thereof and optionally with third intermediate area IC defined by an intermediate cross section area of adjacent rows and adjacent columns of solar cells 2 in the array arrangement, wherein the solar panel 1 further comprises a light scattering area 12 for scattering light towards the solar cells 2; the light scattering area 12 corresponding substantially with a location of either the first intermediate area IA, the second intermediate area IB, the third intermediate area IC, or a combination thereof, and wherein the light scattering area 12 is a light scattering layer arranged at a same level L1 substantially perpendicular from the front side plate 4 as a level of the solar cells 2 between the front side plate 4 and the rear side plate 6, the light scattering layer being embedded between an upper and lower encapsulant layer.

1-16. (canceled)

17. Solar panel (1) for receiving light from a radiation source comprising a plurality of semiconductor substrate based solar cells (2), a transparent front side plate (4), and a rear side plate (6);
the transparent front side plate (4) being stacked on top of the rear side plate (6); the plurality of solar cells (2) being arranged in an array in between the rear side (6) plate and the front side plate (4), each solar cell (2) having a light receiving surface facing (8) towards the front side plate (4);
the solar cells (2) being embedded in an encapsulant layer (10) between the front side plate (4) and the rear side plate (6), wherein
the solar panel comprises between the front side plate and the rear side plate internal light redirection means (12;
20) for guiding light received on the solar panel (1) but not captured by the solar cells (2), towards the solar cells (2),
wherein the solar panel further comprises a frame (14) or an edge and the solar cells (2) are placed at predetermined positions (d1, d2) relative to each other with a first intermediate area (IA) between each two adjacent solar cells (2) and a second intermediate area (IB) between the frame (14) or edge and each solar cell (2) adjacent to the frame (14) or the edge, and optionally with a third intermediate area (IC) defined by an intermediate cross section area of adjacent rows and adjacent columns of solar cells (2) in the array arrangement,
wherein the internal light redirection means of the solar panel (1)is a light scattering area (12) for scattering light towards the solar cells (2); the light scattering area (12) corresponding substantially with a location of either the first intermediate area (IA), the second intermediate area (IB), the third intermediate area (IC), or a combination thereof, and
wherein the light scattering area (12) is a light scattering layer arranged for scattering at least a portion of light originating from the radiation source, and the light scattering layer is applied to the front side glass plate between the front side glass plate (4) and the encapsulant layer (10) that embeds the solar cells (2) in the solar panel (1).

18. The solar panel according to claim 17, wherein the light scattering area (12) is arranged for scattering at least a portion of light originating from the radiation source.

19. The solar panel according to claim 17, wherein the light scattering area (12) is a colored light scattering layer, arranged for absorbing visible light portion from the radiation source and for scattering at least a portion of light originating from the radiation source, the portion of light being in the (near) infrared range of the spectrum.

20. The solar panel according to claim 17, wherein the light scattering layer comprises a substance having light scattering particles therein.

21. The solar panel according to claim 17, wherein the light scattering layer is embodied by a patterned foil with openings (18), each with a size corresponding with the size of a solar cell (2) and the pattern of openings (18) corresponding with the positions of the solar cells (2) in the array.

22. The solar panel according to claim 21, wherein the patterned foil comprises a polymer with a melting point higher than a lamination temperature required in the manufacturing of the solar panel.

23. The solar panel according to claim 20, wherein the substance is a paint or an ink.

24. The solar panel according to claim 20, wherein the light scattering layer is one selected from a group comprising a paint or ink layer, a sticker, a foil, a gasket, a tape, or a laminated sheet that comprises the substance having light scattering particles therein.

25. The solar panel according to claim 17, wherein the rear side plate (6) is transparent to light.

26. The solar panel according to claim 25, wherein the solar cells (2) are bifacial solar cells.

27. The solar panel according to claim 17, wherein the solar cells (2) are interconnected in the array by tab connections (28) or bussings.

28. The solar panel according to claim 27, wherein the tab connections (28) and/or bussings are covered by the light scattering area (12) in a direction towards at least one of the front side plate (4) and the rear side plate.

29. Solar panel (1) for receiving light from a radiation source comprising a plurality of semiconductor substrate based solar cells (2), a transparent front side plate (4), and a rear side plate (6);
the transparent front side plate (4) being stacked on top of the rear side plate (6); the plurality of solar cells (2) being arranged in an array in between the rear side (6) plate and the front side plate (4), each solar cell (2) having a light receiving surface facing (8) towards the front side plate (4);
the solar cells (2) being embedded in an encapsulant layer (10) between the front side plate (4) and the rear side plate (6), wherein
the solar panel comprises between the front side plate and the rear side plate internal light redirection means (12; 20) for guiding light received on the solar panel (1) but not captured by the solar cells (2), towards the solar cells (2),
wherein the solar panel further comprises a frame (14) or an edge and the solar cells (2) are placed at predetermined positions (d1, d2) relative to each other with a first intermediate area (IA) between each two adjacent solar cells (2) and a second intermediate area (IB) between the frame (14) or edge and each solar cell (2) adjacent to the frame (14) or the edge, and optionally with a third intermediate area (IC) defined by an intermediate cross section area of adjacent rows and adjacent columns of solar cells (2) in the array arrangement,
wherein the internal light redirection means of the solar panel (1)is a light scattering area (12) for scattering light towards the solar cells (2); the light scattering area (12) corresponding substantially with a location of either the first intermediate area (IA), the second intermediate area (IB), the third intermediate area (IC), or a combination thereof, and
wherein the light scattering area (12) is a coloured light scattering layer arranged for scattering at least a portion of light originating from the radiation source, the portion of light being in the (near) infrared range of the spectrum,
and the light scattering layer is embodied by a patterned foil with openings (18), each with a size corresponding with the size of a solar cell (2) and the pattern of openings (18) corresponding with the positions of the solar cells (2) in the array,
and the patterned foil comprises a polymer with a melting point higher than a lamination temperature required in the manufacturing of the solar panel.

30. Method for manufacturing a solar panel (1) comprising:
providing a transparent front plate (4) and a rear plate (6);
providing a plurality of solar cells (2), each being based on a semiconductor substrate and capable of generating photoelectricity from captured radiation energy;
arranging the solar cells in between the transparent front side plate and rear side plate, the solar cells being arranged in an array in between the rear side (6) plate and the front side plate (4), each solar cell (2) having a light receiving surface facing (8) towards the front side plate (4),
and the solar cells being embedded in an encapsulant layer (10) between the front side plate and the rear side plate;
and arranging in the solar panel between the front side plate and the rear side plate internal light redirection means (12; 20) for guiding light received on the solar panel (1) but not captured by the solar cells (2), towards the solar cells (2), wherein the solar panel further comprises a frame (14) or an edge and the solar cells (2) are placed at predetermined positions (d1, d2) relative to each other with a first intermediate area (IA) between each two adjacent solar cells (2) and a second intermediate area (IB) between the frame (14) or edge and each solar cell (2) adjacent to the frame (14) or the edge, and optionally with a third intermediate area (IC) defined by an intermediate cross section area of adjacent rows and adjacent columns of solar cells (2) in the array arrangement,
wherein the internal light redirection means of the solar panel (1) is a light scattering area (12) for scattering light towards the solar cells (2); the light scattering area (12) corresponding substantially with a location of either the first intermediate area (IA), the second intermediate area (IB), the third intermediate area (IC), or a combination thereof, and the light scattering layer is applied to the front side plate, between the front side plate (4) and the encapsulant layer (10) that embeds the solar cells (2) in the solar panel (1).
